(19) United States
(12) Patent Application Publication
(10) Pub. No.: US 2026/0142662 A1
(43) Pub. Date: May 21, 2026

(54) MULTI-LOOP FREQUENCY TRANSLATOR WITH REDUCED AREA/POWER

(71) Applicant: Shaoxing Yuanfang Semiconductor Co., Ltd., Shaoxing (CN)

(72) Inventors: Akash Gupta, Bangalore (IN); Sandeep Sasi, Bangalore (IN); Ankit Seedher, Bangalore (IN); Rakesh Kumar Gupta, Bangalore (IN); Raja Prabhu J, Bangalore (IN); Jeevabharathi G, Bangalore (IN); S Sajeeth Raj, Bangalore (IN); Varun G S, Bangalore (IN)

(21) Appl. No.: 19/363,667

(22) Filed: Oct. 21, 2025

(30) Foreign Application Priority Data
Nov. 19, 2024 (IN) 202441089641

(51) Int. Cl. H03L 7/07; H03L 7/093; H03L 7/197; H04L 7/033

(52) U.S. Cl. CPC H03L 7/07; H03L 7/093; H03L 7/1976; H04L 7/033

(57) ABSTRACT

A multi-loop frequency translator (MLFT) for generating an output clock based on one or more clock sources includes multiple loops. The multiple loops include a primary loop and multiple secondary loops according to a hierarchy. The primary loop is highest in the hierarchy and each of the secondary loops is completed by components of loops higher in the hierarchy. Each loop at a lower level provides a corresponding correction signal to correct any drift from a specification frequency of a respective loop at one or more of the loops at higher levels. The primary loop is an open-loop circuit. In an embodiment, the open-loop circuit is a fractional frequency divider.

### PRIORITY CLAIM

The instant patent application is related to and claims priority from the co-pending India provisional patent application entitled, “Multi Loop PLL based Frequency Translator/Jitter Attenuator/Network Synchronizer”, Serial No.: 202441089641, Filed: 19 Nov. 2024, Attorney docket no.: AURA-369-INPR, which is incorporated in its entirety herewith to the extent not inconsistent with the description herein.

### RELATED APPLICATION

The present application is related to the co-pending application Entitled, “Cascaded Multi-Loop Phase Locked Loop (PLL) Tolerant to Failure of Intermediate Loops”, Ser. No. 19/340,943, filed on 26 Sep. 2025, attorney docket number: AURA-074-US, which is incorporated in its entirety herewith to the extent not inconsistent with the description herein.

### BACKGROUND

### Technical Field

Embodiments of the present disclosure relate generally to frequency translators, and more specifically to a multi-loop frequency translator with reduced area/power.

### Related Art

A frequency translator is used for generating an output clock with a desired frequency that has a scaled value of the frequency of an input clock (from which the output clock is derived). The frequency of the output clock can be a multiple or a fraction of that of the input clock. Often, the output and input clocks are also synchronous, i.e., have a fixed phase relation with each other.

Frequency translators are often realized using a multi-loop architecture, with the

primary loop being designed to provide the output clock, while the other loops operating to correct any drift/errors in the primary loop. The loops may be cascaded hierarchically such that the primary loop is corrected by a next (lower) loop in the hierarchy, which in turn is corrected by the next (lower) loop in the hierarchy. In general, the lower-level loops operate with higher accuracy and/or frequency stability.

It is generally desirable that such multi-loop frequency translators be implemented with reduced area and/or power.

### BRIEF DESCRIPTION OF THE VIEWS OF DRAWINGS

Example embodiments of the present disclosure will be described with reference to the accompanying drawings briefly described below.

FIG. 1 is a block diagram illustrating the details of a multi-loop frequency translator (MLFT), in an embodiment of the present disclosure.

FIG. 2 is a timing diagram illustrating the operation of a fractional frequency divider used in a MLFT, in an embodiment of the present disclosure.

FIG. 3 is a diagram used to illustrate the manner in which changes in the frequency of an output clock of a MLFT due to clock drift of a source clock are nullified, in an embodiment of the present disclosure.

FIG. 4 is a block diagram illustrating the details of a MLFT, in another embodiment of the present disclosure.

FIG. 5 is a block diagram illustrating the details of a MLFT in yet another embodiment of the present disclosure.

FIG. 6 is a block diagram of an example system incorporating a MLFT implemented according to various aspects of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A multi-loop frequency translator (MLFT) provided according to aspects of the present disclosure includes multiple loops. The multiple loops include a primary loop and multiple secondary loops according to a hierarchy. The primary loop is highest in the hierarchy and each of the secondary loops is completed by components of loops higher in the hierarchy. Each loop at a lower level provides a corresponding correction signal to correct any drift from a specification frequency of a respective loop at one or more of the loops at higher levels. The primary loop is an open-loop circuit.

In an embodiment, the open-loop circuit is a fractional frequency divider.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Multi-loop Frequency Translator

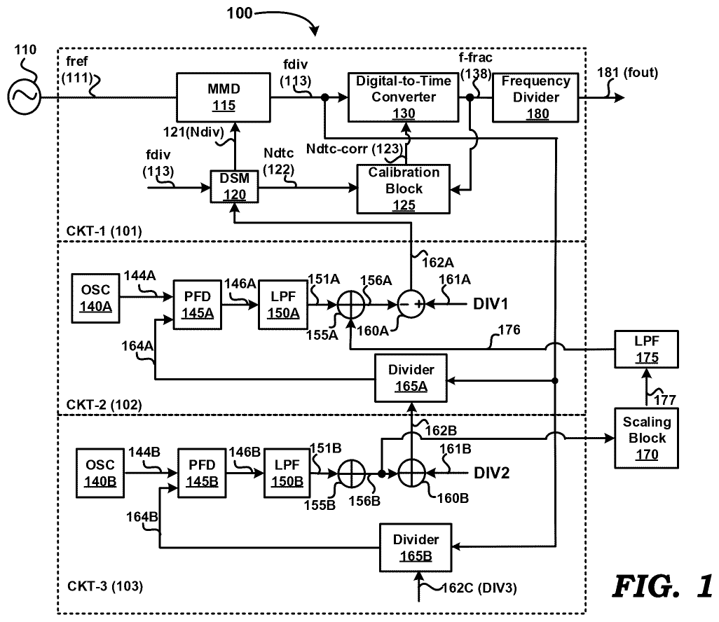

FIG. 1 is a block diagram illustrating the details of a multi-loop frequency translator (MLFT) in an embodiment of the present disclosure. MLFT 100 is shown containing frequency dividers 115, digital-to-time converter (DTC) 130, calibration block 125, delta-sigma modulator (DSM) 120, frequency divider 180, oscillators (or clock generators in general) 140A-140B, phase frequency detectors (PFD) 145A-145B, low-pass filters (LPF) 150A-150B, LPF 175, frequency dividers 165A and 165B, adders 155A, 155B, 160A and 160B and scaling block 170. Dividers receiving correction from other loops are typically each a fractional-N divider with an associated delta sigma modulator for frequency synthesis.

Also shown in FIG. 1 is a clock generator 110 that generates clock 111 (fref). Clock

source 110 may be, for example, a low-jitter high-frequency standalone oscillator and may employ micro-electro mechanical (MEMS) resonators, bulk acoustic wave (BAW) resonators, or be derived from another phase-locked loop (PLL).

MLFT 100 is shown as having three portions, namely CKT-1 (101), CKT-2 (102) and CKT-3 (103), each respectively made of the blocks inside the corresponding dashed boxes. CKT-1 (101) represents a fractional frequency divider that is referred to herein as a primary loop (loop-1).

As may be readily appreciated, the fractional frequency divider is realized in the form of an open-loop circuit since the phase and frequency of fout 181 (or f-frac 138 or fdiv 113) are not impacted by any feedback mechanism. As described in sections below, calibration block 125 also does not impact the phase and frequency of fout 181.

The combination of CKT-1 (101) and CKT-2 (102) represents a ‘secondary loop’ (loop-2) and the combination of CKT-1 (101), CKT-2 (102) and CKT-3 (103) represents another ‘secondary loop’ (loop-3). The secondary loops may be viewed as ‘cascaded loops’. The loops together form a hierarchy, with the primary loop (loop-1) being at the highest level (top) of the hierarchy, loop-2 being immediately lower to loop-1, and loop-3 being immediately lower to loop-2. The frequency dividers of CKT-2 and CKT-3, namely 165A and 165B each receives fdiv (113) as input in the embodiment shown in FIG. 1. However, in other embodiments, f-frac (138) can be provided as input instead of fdiv (113) to these frequency dividers.

Each secondary loop is completed by components of loops higher in the hierarchy. Such an observation holds even if one of the intermediate loops fails and the corresponding bypass circuit is operational (as further described below in detail). For example, assuming that CKT-3 (103) fails, then loop 3 would contain components of CKT-2 and CKT-1 (but not those of CKT-3) due to the corresponding bypass path.

It is noted here that, typically, the frequency-stability and/or accuracy of the clock sources generating clocks 111, 144A and 144B are in increasing order. Thus, clock 111 is least accurate/frequency-stable, clock 144A is more frequency-stable/accurate than clock 111, and so on. Instead of having a local clock source as shown in FIG. 1, one or more of the outer (i.e., secondary) loops may receive a clock generated externally in the network, as illustrated with respect to an alternative embodiment below.

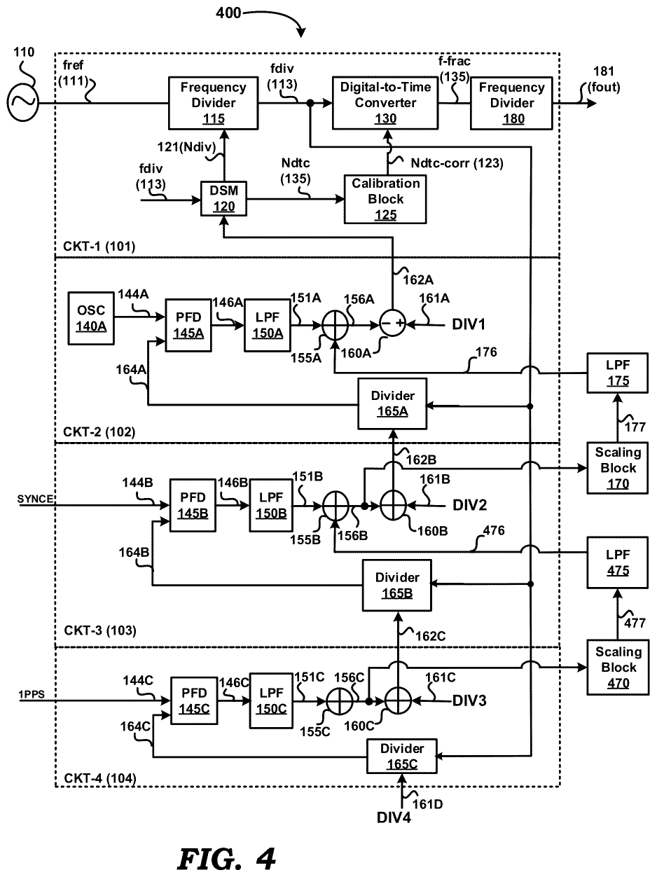

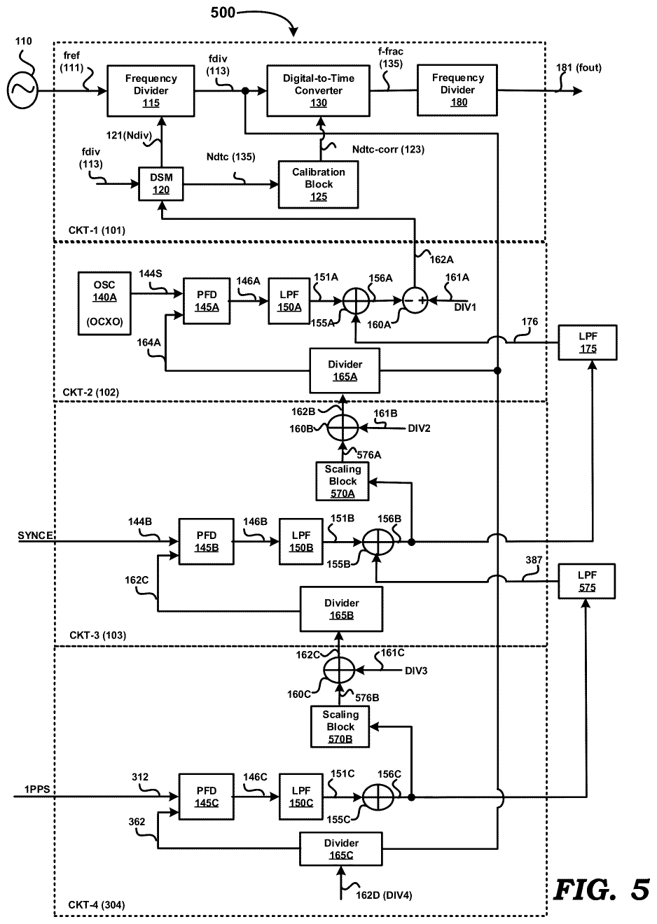

Some alternative embodiments (e.g., as in FIGS. 4 and 5) may contain more secondary loops successively lower in the hierarchy. In an embodiment of the present disclosure, CKT-1 is a fractional frequency divider. CKT-2 and CKT-3 are each PLLs implemented completely using digital circuits/blocks except for oscillators 140A and 140B. However, in other embodiments, CKT-1 (101), CKT-2 (102) and CKT-3 (103) can be implemented in a different manner, with CKT-1 specifically being an open-loop structure/circuit. The combination of blocks 170 and 175 represents a ‘bypass circuit’ or bypass path (BP-1).

In some embodiments, one or both of oscillators 140A and 140B (together referred to as oscillators 140) may not be implemented integral to MLFT 100 (which is itself implemented as an integrated circuit), and their clocks 144A-144B may instead be received from an external source.

Referring to CKT-1 (101), the circuit represents a fractional frequency divider that receives a clock fref (111) as input. CKT-1 receives a fractional divisor of the form M. N (e.g., 4.25) on path 162A, wherein M and N are integers and ‘.’ represents the decimal point. CKT-1 divides the frequency of clock fref by the fractional number M. N to generate output clock fout (181). The details of CKT-1 are briefly described next.

### 3. Open-loop Modulator

CKT-1 is implemented as an open-loop modulator. The term ‘open-loop’ implies that there are no feedback loops in the structure/circuit. As may be observed from CKT-1 in FIG. 1, by itself (i.e., ignoring the connections from CKT-2 to CKT-1), CKT-1 is an open-loop circuit. A PLL in contrast is a closed-loop circuit since it contains a feedback loop. The term ‘modulator’ implies that the circuit changes (modulates) the frequency of the input clock (here by dividing the frequency). In FIG. 1, CKT-1 is shown implemented as an open-loop fractional divider (Fractional Frequency Divider (FFD)).

FFD (101) is shown containing delta-sigma modulator (DSM) 120, multi-modulus frequency-divider (MMD) 115, digital-to-time converter (DTC) 130, calibration block 125 and frequency divider 180. FFD 101 receives an input clock fref and divides its frequency by a fractional number (Int+num/den), wherein ‘Int’ stands for ‘integer, ‘num’ stands for numerator and ‘den’ stands for denominator. Fractional division is realized using a delta-sigma modulator (DSM). A DTC (digital to time converter) performs phase adjustment of pertinent clock edges of the output of the MMD to cancel the quantization noise contributed by the DSM. Calibration block 125 may be implemented only if errors in the gain (output/input) of DTC 130 are present (or expected during operation due to changes in temperature, etc.). When calibration block 125 is not implemented, DTC 130 receives Ndtc (122) directly.

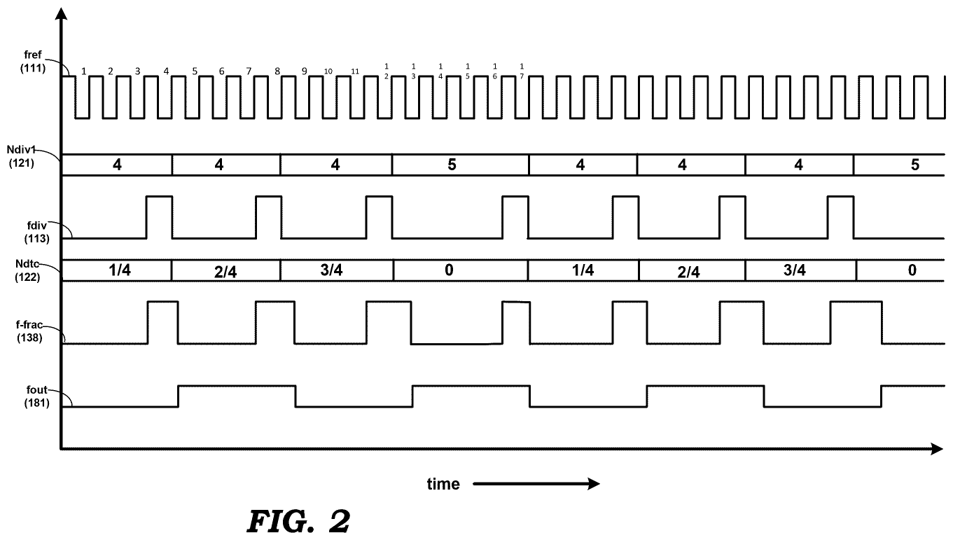

DSM 120 represents a delta-sigma modulator. DSM 120 receives a desired ‘fraction’ (divisor DIV1 on path 161A received via path 162A) by which the frequency of fref (111) is to be divided Signal fdiv (113) is applied to DSM 120 and controls the operation of DSM 120. DSM 120 updates the values Ndiv and Ndtc once in every cycle of fdiv (113). (The operation of adder 160A and the value on path 156A is ignored for now.). Divisor DIV1 may be received in the form of an integer-component and a fractional-component from an external source, for example, from a user input. To realize fractional division of fref by the value of divisor (DIV1), DSM 120 operates to cause MMD 115 to divide fref (111) by values generated on path 121 (Ndiv), and DTC 130 to delay corresponding edges of the divided clock fdiv (113) generated by MMD 115. Such operation to achieve fractional frequency division is well-known in the relevant arts, and is only briefly illustrated herein (with reference to FIG. 2). DSM 120 may be implemented in a known way.

MMD 115 receives reference clock fref on path 111 and code Ndiv on path 121. MMD 115 is a multi-modulus (integer) frequency divider which divides the frequency of fref by the value Ndiv to generate clock fdiv (113). Ndiv is received (and applied by MMD 115) in every cycle of fdiv.

DTC 130 is a digital-to-time converter that operates to delay pertinent edges of clock fdiv by a duration specified by a corresponding ‘corrected’ code Ndtc-corr received on path 123 to generate clock f-frac on path 138. DTC 130 may be implemented, for example, using resistor-capacitor delay banks, in a known way.

Calibration block 125 modifies each value of Ndtc to delay edges (e.g., falling edges) of MMD 115, without altering the phase or frequency of the input of DTC 130. Gain-error refers to error in the ratio of the delay provided to the corresponding code (Ndtc 122 in FIG. 1). Calibration block 125 may be implemented in a known way. In an embodiment, calibration block 125 operates on clock f-frac as an input. In some embodiments such as for example those in which no substantial gain-error exists or occurs, or in which such errors can be either mitigated or tolerated, calibration block 125 is not implemented, and values on path 122 (Ndtc) are directly provided to DTC 130.

Frequency divider 180 operates to divide the frequency of f-frac by two to generate output clock fout on path 181. The division by 2 results in fout having a 50% duty cycle. The frequency of fout is 1/(2*DIV1) that of fref. It is noted that divisor DIV1 is the ratio of the frequency of fref (111) to that of f-frac (138). Frequency divider 180 provides a further division by 2 of f-frac to generate fout (181). The division by 2 is provided to generate a clock with a 50% duty cycle. If a 50% duty cycle is not desired, f-frac may be directly provided as the output of MLFT 100 (not shown in FIG. 1). When fout is instead used, divisor (DIV1) may be scaled by a factor of 2 to result in a frequency of fout that is a desired fraction of fref.

FIG. 2 is a timing diagram that illustrates the operation of FFD 101 for an example fractional division of fref by 4.25 to generate f-frac. In the illustration, DTC 130 is assumed to have no gain-errors, with Ndtc values and the corresponding Ndtc-corr values being identical. As illustrated in FIG. 2, DSM 120 generates a sequence of correlated code-pairs on its outputs Ndiv (121) and Ndtc (122) in corresponding cycles of fdiv (113). The first value of the pair is an integer divisor (to be used by MMD 115) and the second value of the pair indicates a desired delay (to be applied to corresponding edges of fdiv by DTC 130).

In FIG. 2, waveforms or values of fref, Ndiv, fdiv, Ndtc, f-frac and fout are shown for a fractional division of fref by 4.25 (integer component being ‘4’ and fractional component being ‘0.25). DSM 120 is shown as generating a repeating sequence of integer divisors 4, 4, 4, and 5 on Ndiv (121), and a sequence of delay values ¼, 2/4, ¾ and 0 on Ndtc (122). The effect is to generate f-frac (138) with a frequency that is 1/(4.25) that of fref, as may be verified from FIG. 2 (there are 4 cycles of f-frac for every 17 cycles of fref).

As may be observed from FIG. 2, the frequency of fdiv is not constant, and changes whenever the value of Ndiv changes. DTC 130 operates to delay edges of interest (falling edges in the examples noted herein) of clock fdiv according to the digital values received on Ndtc-corr (123). The effect of the delays caused by DTC 130 is to generate f-frac with falling edges such that the intervals between successive falling edges are all equal.

As may be readily appreciated, the rising edges of clock Fdiv 113 are unaltered by any of the blocks (calibration block 125 and DTC 130) and thus the frequency and phase are unaltered.

Continuing with reference to FIG. 1, CKT-2 (102) is a PLL (along with DSM 120 and MMD 115 of CKT-1). Oscillator 140A generates a clock on path 144A. PFD 145A receives clock 144A and a feedback clock from divider 165A on path 164A, and operates to generate, on path 146A, an error signal indicating a phase difference between clocks 144A and 164A. LPF 150A is a low-pass loop filter that accordingly filters error signal 146A to generate a filtered output (in the form of a number/digital value) on path 151A. Adder 155A adds the digital values on paths 151A and 176, and forwards the sum on path 156A. Adder 160A adds the digital values on paths 156A and 161A (DIV1), and forwards the sum on path 162A. However, the input on path 156A is multiplied by −1 prior to addition with the value on path 161A, as indicated in FIG. 1 by a ‘−’ sign at the input of adder 160A connected to path 156A. DSM 120 applies the sum received on path 162A, recomputes and provides new values of Ndiv and Ndtc at every clock edge of fdiv (113). DIV1 on path 161A is as noted above. Divider 165A divides the frequency of clock fdiv (113) by a number/digital value received as input on path 162B to generate feedback clock 164A. The number on path 162B is the sum of a fixed value (DIV2) provided on path 161B (for example by user input or other suitable approach). The number on path 156A can vary with time based on factors that are further described below. The combination of the corresponding portions (DSM 120 and MMD 115) of CKT-1 and CKT-2 represents a secondary loop (loop-2) formed by the blocks ‘DSM 120—MMD 115—divider 165A—PFD 145A—LPF 150A—adder 155A and adder 160A’. In the absence of signal 176 (i.e., when bypass path BP-1, described below, is not implemented), adder 155A is not present, and signals 151A is directly provided to adder 160A as an input.

Referring to CKT-3 (103), oscillator 140B generates a clock on path 144B. PFD 145B receives clock 144B and a feedback clock from divider 165B on path 164B, and operates to generate, on path 146B, an error signal indicating a phase difference between clocks 144B and 164B. LPF 150B is a low-pass loop filter that accordingly filters error signal 146B to generate a filtered output (in the form of a number/digital value) on path 151B. Adder 155B is shown in FIG. 1 for consistency in structure of CKT-3 with CKT-2, but does not perform any addition. Instead, in the embodiment of FIG. 1, adder 155B merely forwards digital value 151B on path 156B. Adder 160B adds the digital values on paths 156B and 161B (DIV2), and forwards the sum on path 162B. Divider 165B divides the frequency of fdiv (113) by a number/digital value received as input on path 162C (DIV3) to generate feedback clock 164B. DIV3 is a fixed value provided by user input or other suitable approaches. The combination of CKT-1, CKT-2 and CKT-3 represents another secondary loop (loop-3) formed by the blocks ‘divider 165B—PFD 145B—LPF 150B—adder 155B—adder 160B—divider 165A—PFD 145A—LPF 150A—adder 155A—adder 160A—DSM 120 and MMD 115’.

Scaling block 170 performs a scaling operation by multiplying the value on path 156B by the factor (DIV1/DIV2), and forwards the scaled value on path 177 to low pass filter (LPF) 175. LPF 175 has a bandwidth equal to (or substantially equal to) that of loop-2 and accordingly filters the input on path 177. LPF 150A partially determines the bandwidth of loop-2. Other factors such as the frequency of reference clock 111, gain of PFD 145A, etc., also determine the bandwidth. In an embodiment, the bandwidth is determined mainly by LPF 150A. LPF 175 forwards the filtered values onto path 176 to adder 155A of CKT-2. The use of LPF 175 is optional. Thus, in another embodiment, LPF 175 is not implemented and the output of scaling block 170 is directly provided to adder 155A. Scaling blocks 170 and LPF 175 together form a ‘bypass path’, as further described below.

Each of frequency dividers 165A and 165B is implemented as a fractional divider (i.e. divide by a fraction greater than one) employing, for example, delta-sigma modulators as is well known in the relevant arts.

Clock generator 110 (which is external to MLFT 100), 140A and 140B are selected/designed to generate clocks fref (111), 144A and 144B respectively (generically referred to herein as ‘source clocks’) with desired frequencies according to the specification/design of MLFT 100. However, one or both of clocks 144 can instead be received (with a known frequency) from external sources. The desired frequencies per design or specification are referred to herein as ‘specification frequencies’. Accordingly, each of loops loop-1, loop-2 and loop-3 may also be viewed as having the corresponding ‘specification frequency’.

DIV2 is set to a value such that the frequency of fdiv 113 on an average (which would be equal to the frequency of f-frac) is equal to the product of DIV2 and the frequency of clock 144A. Similarly, DIV3 is set to a value such that the frequency of f-frac is (also) equal to the product (DIV3*frequency of clock 144B), wherein the symbol ‘*’ represents the multiplication operator. As an illustration, clock generator 110, and oscillators 140A and 140B may be designed to generate respective clocks 111, 144A and 144B with respective frequencies of 9.6 GHz (Giga Hertz), 10 MHz and 1 MHz. In such an example, loop-1, loop-2 and loop-3 may be viewed as having respective specification frequencies of 9.6 GHz, 10 MHz and 1 MHz respectively, and in steady-state operation of MLFT 100, each of the products (1/DIV1*9.6 GHz), (DIV2*10 MHz) and (DIV3*1 MHz) equals the (desired) frequency of f-frac (138).

The arrangement of the loops in MLFT 100 enables a loop lower in the hierarchy to correct for changes in the frequency of f-frac (138) due to oscillator drift of one or more loops higher in the hierarchy. Thus, and ignoring signal 176 for the moment, the coupling via path 162A between CKT-2 and CKT-1 enables CKT-2, or more precisely, loop-2 to correct for any change (or drift) in the frequency of clock fref (111), and therefore of clocks f-frac and fout, from their respective desired values. For example, assuming MLFT 100 has reached steady-state operation (e.g., after power-up), each of the products (1/DIV1*9.6 GHz), (DIV2*10 MHz) and (DIV3*1 MHz) equals the (desired) frequency of f-frac (138).

Denoting, the (desired) frequency of f-frac (138) also as f-frac:

f-frac=(1/DIV1)*9.6 GHz=DIV2*10 MHz=DIV3*1 MHz (1)

In general,

f-frac=(1/DIV1*(freq−111)=DIV2*(freq−144A)=DIV3*(freq−144B) (2)

wherein, freq−111 is the frequency of clock 111,
freq−144A is the frequency of clock 144A, and
freq−144B is the frequency of clock 144B.

From the steady-state condition, if the frequency of oscillator 111 were to change (for example, due to ‘oscillator drift’ because of temperature-changes and/or other reasons), then f-frac (and fout) would change. As a result, the phase/frequency of feedback clock 164A of CKT-2 would change. Therefore, loop-2 would react to such change. In particular, and assuming that there is no change in the frequency of clock 144A, PFD 145A would now generate a corresponding error signal proportional to the current phase error between clocks 144A and 164A. Correspondingly, the value on path 156A, and therefore path 162A, would change from its previous steady-state value, with the change representing a correction provided by loop-2 to loop-1 via DSM 120. Since frequency of clock 144A and the value of DIV1 have not changed, the ‘correction’ on path 162A would operate to bring the frequency of f-frac (and fout) back to its desired value. In general, if the ‘frequency-stability’ of the clock source that generates clock 144A is better (greater) than that of the clock source that generates 111, then the frequency-stability of clock f-frac and output clock fout would be as good as that of the source that generates clock 144A. In other words, frequency f-frac is termed as ‘tracking’ the frequency of clock 144A. In other words, the frequency drift of f-frac would be only as bad as that of clock 144A.

In a manner similar to that noted above, the coupling via path 162B between CKT-3 and CKT-2 enables loop-3 to correct for any drift in the sources of clock 144A and 111. Thus, each loop at a lower level provides a corresponding correction signal to correct any drift from a specification frequency of one or more loops at higher levels. This would, in general, be true if the frequency-stability of the source that generates clock 144B is greater than that of the source that generates clock 144A, and the source that generates clock 144A is greater than that of the source that generates clock 111.

In the embodiments described herein, the bandwidths (BW) of loops loop-1, loop-2 and loop3 are in descending order. That is, BW of loop-1 is greater than that of loop-2, and BW of loop-2 is greater than that of loop-3. The respective loop bandwidths are substantially (but not entirely) determined by the bandwidths of LPFs 150A and 150B respectively. In some other alternative embodiments, the relation between the loop bandwidths can be different. Also, the phase jitter of source clocks 111, 144A and 144B are in increasing order of magnitude. That is, phase jitter of clock 111 is smaller than that of clock 144A, whose phase jitter is smaller than that of clock 144B.

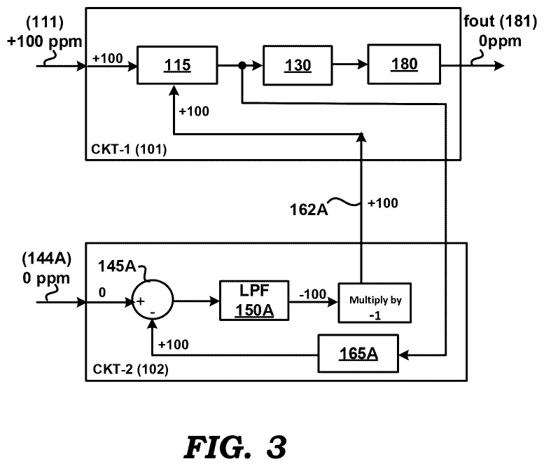

FIG. 3 illustrates a frequency-correction example. The clock frequencies noted in FIG. 3 are indicated in terms of ppm (parts per million). As used herein, +/-X ppm means a frequency that is away from a specification frequency by X ppm, i.e., X ppm above the specification frequency or X ppm below the specification frequency. To illustrate with an example, assuming the specification frequency is 100 Mega Hertz (MHz), a clock with a frequency expressed as −100 ppm would have a frequency [100*(1−(100/1000000))] MHz, i.e., 99.99 MHz (Mega Hertz). In the example of FIG. 3, clock 111 is +100 ppm and clock 144A is 0 ppm.

Clock 111 being at +100 ppm can imply that clock 111 was 0ppm initially (say upon first deployment of MLFT 100 or upon power ON, but drifted to +100 ppm due to temperature change during operation. Alternatively, clock 111 being at +100 ppm can imply that clock 111 (or its source) inherently has a frequency inaccuracy. Either way, the frequency drift or frequency inaccuracy of clock 111 would cause clocks f-frac and fout to also have a corresponding frequency error that would also be +100 ppm without correction (via 162A) from the next outer loop (CKT-2 +CKT-1). Therefore, the output of divider 165A would also be +100 ppm immediately prior to the beginning of correction—i.e., when the outer loop starts to react. As a result, the output of (PFD 145A+LPF 150A) would generate a correction signal on path 162A that corresponds to −100 ppm in steady state. Since the correction is applied to change the divisor of MMD (115) via DSM 120, a multiplication by −1 is needed, and is shown done in the ‘multiply by −1’ block to generate a +100 ppm correction. As a result, in steady-state, the divisor employed by DSM 120 would be correspondingly increased by +100 ppm in this example, so as to nullify the +100 ppm error in clock 111. This, in turn, would reduce the error in f-frac as well as fout (181) to 0 ppm, i.e., no error in steady-state. To summarize, since fdiv equals fref/DIV1, if fref is +100 ppm away from its ideal frequency, then to reduce fdiv, DIV1 must be increased by +100 ppm.

Loop-3 can similarly correct for frequency errors in fout due to errors/drift in one or more of clocks 111 and 144A.

As noted above, failure of operation of an intermediate loop can prevent the primary loop from obtaining (and therefore using) the corrections from one or more of the lower-level loops, or even if made available for use via a direct path (not shown) would cause a disturbance (frequency and phase changes) in output clock 181. In the 3-loop example of FIG. 1, in the absence of scaling block 170 and LPF 175 and the corresponding ‘bypass path’ so formed, if loop-2 were to fail, loop-1 would lose the corrections from loop-3 altogether (as for example, if there is a failure of oscillator 140A, loss of clock 144A or a break (electrical disconnection) in the corresponding paths to/from these blocks).

Alternatively, even if the corrections on path 162B were directly made available to loop-1 (to DSM 120, for example, by means of a corresponding path (not shown) that can be switched ON and OFF, the corrections would introduce undesirable transients on output clock 181.

According to an aspect of the present disclosure, corrections from loop-3 are available to loop-1 even if loop-2 were to fail. Furthermore, the corrections are modified before being provided to loop-1 and thereby enable application of the corrections to loop-1 without causing any (or at least any substantial) disturbance (hit) in the frequency or phase of output clock 181. Such a capability is achieved by implementing a bypass path from node 156B to node 176 containing scaling block 170 and LPF 175. The operation of the bypass path is described next.

### 4. Bypass Path

Before describing the operation of the bypass path, certain features of the loops in the event of their failure are now described briefly. Each of CKT-2, CKT-3 and CKT-4 (FIG. 4) contains a loss-of-clock detection circuitry connected to receive the corresponding source clock, that monitors for presence/occurrence of proper clock cycles of the respective clocks 111, 144A and 144B. Upon loss/failure of the corresponding source clock, the detection circuitry signals a ‘loss-of-clock’ to the corresponding LPF, which causes the loop to operate in a holdover (HO) mode by freezing/holding the last-good value (or a historical average value of) its output. The last-good value is the value immediately prior to loss/failure of the source clock).

Referring to CKT-2, for example, upon loss of clock 144A (or failure of oscillator 140A) or a break in connecting path 144A, loop-2 is designed to go into ‘holdover’ mode, with LPF 150A designed to hold the last-known good/correct value on path 151A. Therefore, one input (value 151A) to adder 155A is fixed and constant. The other input is received through the bypass path, i.e., ‘path 156B—scaling block 170—path 177-LPF 175—path 176’. In an embodiment, scaling block 170 is designed to multiply the value on path 156B by the ratio DIV1/DIV2. The resulting product is low-pass filtered by LPF 175 and is provided as another input to adder 155A via path 176.

Failure of loop-2 can occur due to the reasons noted above. Failure of a loop implies that the correction from that loop is stopped from being updated (as the loop has transitioned to holdover mode) and LPF 150A would hold its last (good) output value (or a historical average). Thus, failure of loop-2 implies that, ignoring the output of the bypass path, the value(s) on path 162A will no longer be able to correct the frequency errors in fref 111.

With all of MLFT 100 operating normally and having reached steady-state operation with output clock 181 being provided at the desired frequency, when failure of loop-2 occurs, the values on path 162B, and therefore corrections from loop-3 to loop-2 via divider 165A are no longer effective. Hence, these corrections cannot propagate via loop-2 to loop-1. However, due to the bypass path, the values on path 156B are propagated to adder 155A after scaling in scaling block 170 and filtering in LPF 175. The scaling in block 170 scales the values on path 156B by a factor DIV1/DIV2 (wherein, ‘/’ represents the division operator). The magnitude of the scaling, i.e., DIV1/DIV2 is shown to be required using an analysis described further below.

The BW of LPF 175 is designed to be equal to that of loop-2. It is noted here that, typically, LPF 150A determines the bandwidth (BW) of loop-2 to a large extent, with the frequency of reference clock 111, PFD 145A's gain, etc., also playing a part. Therefore, corrections on path 156B, which would bypass the low-pass filtering provided by loop-2 when passing through the bypass path instead, are low-pass filtered. Such low-pass filtering using LPF 175 may be necessary when it is desired that the jitter specifications of output clock 181 are not degraded when loop-2 fails and the bypass path provides the corrections. However, if such degradation in jitter-specification of output clock 181 is acceptable, LPF 175 may be omitted and the output of scaling block 170 is directly provided to adder 155A. Effectively, the replica LPF (e.g., 175 in FIG. 1) in a bypass path is used to match the transfer function through the respective loop (e.g., loop-2 in FIG. 1) to maintain the desired Jitter Attenuator Transfer characteristics of MLFT 100.

Due to the appropriate scaling of the correction 156B by scaling block 170, the corrections 156B when applied to adder 155A, and thus to loop-1 will not cause an abrupt jump or disturbance/transient in output clock 181. Therefore, the corrections, if any, correct the frequency of output clock 181 with zero or minimal hit (disturbance) on the phase and/or frequency of output clock 181 even upon loss of an intermediate source clock or in general, failure of the intermediate loop. When MLFT 100 has more than three loops, failure of any one or more intermediate loops allows the primary loop to receive and make use of corrections from an operative loop lower down in the hierarchy than the lowest of the failed intermediate loops, without causing a hit/disturbance in output clock 181.

It may be observed that, when loop-2 is operational, the corrections via the bypass path

on path 176 are concurrently applied with the corrections via path 162B. Ignoring the effect of the bypass path for now, i.e., assuming that the bypass path containing scaling block 170 and LPF 175 were not present, from or following a steady-state condition of output clock 181, a signal value of X at node 156A represents a correction of [(X/DIV1)*1000000] in terms of ppm. If the bypass path is required to provide the same effect as X at node 156A, then the input to the bypass path, i.e., a magnitude Y at node 156B when scaled by scaling block 170 must equal [(X/DIV1)*1000000] in terms of ppm. Now, magnitude/value Y at node 156B represents a correction of [(Y/DIV2)*1000000] in terms of ppm. Therefore, [(X/DIV1)*1000000] should equal [(Y/DIV2)*1000000]. Hence, X/DIV1=Y/DIV2, i.e., X=Y*(DIV1/DIV2). The gain of LPF is 1. With loop-2 in hold-over, all of the change X must come from the bypass path. Therefore, the magnitude at node 177 must also equal X. Hence, the scaling provided by scaling block 170 must equal DIV1/DIV2. The scaling factor (DIV1/DIV2) is provided by scaling block 170 as noted above.

When the bypass path is present, and when all loops are operational, in response to a change in frequency of fout, loop-2 will attempt to generate a correction at node 151A and loop-3 will attempt to generate a correction at node 176 via the bypass path. The correction at node 176 will be generated since loop-3 is the lowest loop in the set. However, the correction at node 176 will cause any ‘additional’ correction at node 151A to be ‘pushed back’ and effectively no change would occur to the value at node 151A, which would remain unchanged.

It may be appreciated that the simultaneous application of the corrections via the bypass path even when loop-2 is operational ensures that in the event of failure of loop-2, LPF 150A would hold/freeze its last known good value on path 151A. Since corrections 176 from the bypass path have continuously been applied to adder 155A, corrections 176 immediately following failure of loop-2 will not represent a large step-jump immediately following failure. In other words, corrections 176 would at best be changing only by very small values at, and immediately following failure of loop-2, and would thus be ‘seamless’. As a result, output clock 181 does not manifest a hit or disturbance (i.e., sudden change, or transient, in frequency and phase) that could otherwise linger for a long-time rendering output clock 181 potentially unusable at its destination. Had corrections 176 be applied to adder 155A only upon or after failure of loop-2, then it is possible that the correction could be a large step correction which could cause an unacceptable hit/disturbance in output clock 181, potentially rendering clock 181 unusable.

Due to finite precision used in representing DIV1/DIV2 in scaling block 170, a corresponding quantization error may be introduced in the bypass path. However, such quantization error is compensated or removed during normal operation when no loop fails (here, when loop-2 is still operative). The application of the output of the bypass path to adder 155A even when loop-2 is operative would cause the output 151A to have values which would compensate for the quantization error. Upon failure of loop-2, loop-2 goes into holdover mode and LPF 150A would hold the last value (or historical average) of 151A, which would contain/include the compensation for the quantization error. This is another benefit of operating the bypass path simultaneously even when the corresponding intermediate loop (here loop-2) is operative normally.

The output/correction (e.g., 176) from a bypass path may be viewed as a ‘substitute’ signal provided to a higher loop (e.g., loop-1) when the ‘regular’ correction signal (e.g., 151A) from the immediately lower loop (e.g., loop-2) to the higher loop (e.g., loop-1) is not available (no updates are available) due to failure of the lower-loop (e.g., loop-2), which would then hold the last value or historical average until failure at node 151A. Substitute signal 176 is provided from loop-3 to loop-1, bypassing loop-2. Thus, loop-1 is said to be one ‘skip-level’ (corresponding to loop-2) higher than loop-3 in the hierarchy.

While the embodiments shown herein depict all bypass paths as operating with a single

skip-level, it should be appreciated that alternative embodiments can have bypass paths with more than one skip-level also. Such multiple skip-levels may be particularly suitable when a MLFT has more (than 3) loops to account for situations when more than one intermediate adjacent loops fail.

Further, when a bypass path is not present or implemented, the output of the

corresponding LPF is directly connected to the adder that receives the corresponding fixed divisor. To clarify for example, when bypass path BP-1 is not implemented, adder 155A is not present, and signals 151A is directly provided to adder 160A as an input.

In an embodiment, a MLFT provided according to several aspects of the present

disclosure is used in a network synchronization environment in telecommunication networks, as described next.

### 5. Network Synchronization

As is well-known in the relevant arts, telecommunication networks are used for transmitting and receiving data packets as well as other signals such as single-tone frequency signals. One general requirement in such networks is network synchronization, i.e., various (or all) portions and nodes of the network may all need to maintain time accurately (i.e., their clocks need to tick at the same rate). Accordingly, a master (time-keeper) station transmits current-time (time-of-day or TOD) to various nodes of the network, for example, via boundary stations to slave stations. One use of such TOD information is to time-stamp data packets at one or more nodes in the network as the data packets traverse the network from a source to destination.

One requirement for a MLFT used in a telecommunication network (for example, in a slave station/node or boundary station/node) is as specified in the ITU-T standard G.8273.2. This standard requires the MLFT to be able to generate an output clock to ‘track’ one or more of multiple grades of clocks with different levels of priority/transfer function. Four grades of clocks are specified by the standard, namely XO, OCXO, SYNCE, GPS/1pps/PTP] in order of increasing frequency precision and frequency stability. XO, OCXO, SYNCE and GPS/1pps/PTP respectively denote a clock generated by a crystal oscillator, an oven-controlled crystal oscillator, specified by the Synchronous Ethernet standard, and a 1 pulse-per-second signal/clock obtained using the Global Positioning System (GPS) or Precision Time Protocol.

The specification requires that if all the clocks are available, then the output clock of the MLFT should track GPS/1pps/PTP signal. If GPS/1pps/PTP is lost, then the output clock should track SYNCE. If SYNCE is lost, then the output clock should track OCXO. If OCXO is lost, then the output clock should track XO. The term ‘track’ is used to mean ‘frequency stability should be substantially equal to that of’. In other words, frequency-drift in the input clock that is within the DPLL's BW is exactly tracked at the output clock.

FIG. 4 is a block diagram of a MLFT in another embodiment of the present disclosure. MLFT 400 may be contained in a slave station/node or a boundary station/node of a telecommunication network, and is shown containing CKT-1, CKT-2, CKT-3, CKT-4, LPFs 175 and 475, and scaling blocks 170 and 470. CKT-1, CKT-2, CKT-3, LPF 175 and scaling block 170 are the same as shown in FIG. 1 except any differences noted next, and their detailed description is not repeated again in the interest of conciseness. Oscillator 140A is an oven-controlled oscillator (OCXO). Oscillator 140B is not implemented, and a timing signal (SYNCE) according to the synchronous ethernet standard is received on path 144B. Divider 165B now receives on path 162C correction input that includes the sum of the correction from CKT-4 and a fixed value (DIV3).

Referring to CKT-4(104), a 1 PPS clock (GPS-derived), or alternatively, a PTP timing signal according to the Precision Time Protocol, is received on path 144C. PFD 145C receives clock 144C and a feedback clock from divider 165C on path 164C, and operates to generate, on path 146C, an error signal indicating a phase difference between clocks 144C and 164C. LPF 150C is a low-pass loop filter that accordingly filters error signal 146C to generate a filtered output in the form of a number/digital value on path 151C. Adder 155C forwards the digital values on paths 151C to adder 160C. It is noted that adder 155C need not be implemented, and path 151C can be directly connected to path 156C. Adder 160C adds the digital values on paths 156C and 161C (DIV3), and forwards the sum on path 162C. Divider 165C divides the frequency of fdiv 113 by a number/digital value (DIV4) received as input on path 161D to generate feedback clock 164C. The number on path 161D is a fixed value (DIV4) provided by user input or other suitable approaches. The combination of CKT-1, CKT-2, CKT-3 and CKT-4 represents another secondary loop (loop-4) formed by the blocks ‘PFD 145C—LPF 150C—adder 155C—adder 160C—divider 165B—PFD 145B—LPF 150B—adder 155B—adder 160B divider 165A—PFD 145A—LPF 150A—adder 155A—adder 160A—DSM 120—Divider 115—divider 165C’. Loop-4 is deemed to be the lowest loop in the hierarchy of FIG. 4.

In the embodiments described herein, the bandwidths (BW) of loops loop-1, loop-2, loop-3 and loop-4 are in descending order. That is, BW of loop-1 is greater than that of loop-2, BW of loop-2 is greater than that of loop-3, and the BW of loop-3 is greater than that of loop-4. The respective loop bandwidths are substantially determined by the bandwidths of LPF 150A, LPF 150B and LPF 150C respectively. In some other alternative embodiments, the relation between the loop bandwidths can be different. In an embodiment, the frequencies of clock 111 and OCXO clock 144A are 9.6 GHz and 10 MHz respectively. The frequencies of SYNCE and 1PPS/PTP signals are respectively 1 MHz (or 8 kilo Hertz) and 1 Hz. The frequency accuracy and stability of the 4 source clocks are in descending order: 1PPS>SYNCE>OCXO>fref. Also, the phase jitter of source clocks on respective paths 111, 144A, 144B and 144C are in increasing order of magnitude. That is, phase jitter of clock on 111 is smaller than that of OCXO clock on 144A, whose phase jitter is smaller than that of SYNCE clock on 144B, whose phase jitter is smaller than that of 1 PPS/PTP clock on 144C.

The operation of CKT-4 (and loop-4) is similar to that of the other intermediate loops except that it is larger and also the outermost/lowest loop in the hierarchy. Briefly, 1PPS/PTP clock has the highest accuracy and frequency stability among the source clocks in FIG. 4. Loop-4 corrects any frequency drifts in output clock 181 (due to drifts in any of the other source clocks) by generating correction signals on path 162C. The correction signals 162C change the divisor of divider 165B of loop-3, the change in turn causing a cascading effect of corrections via loop-2 and loop-1 and finally to output clock 181 in a manner similar to that described above with respect to the MLFT of FIG. 1.

The combination of scaling block 470 and LPF 475 represents another bypass path (BP-2). Scaling block 470 performs a scaling operation by multiplying the value on path 156C by the factor (DIV2/DIV3), and forwards the scaled value on path 477 to low pass filter (LPF) 475. LPF 475 has a bandwidth BW3 and accordingly low-pass filters the input on path 477. LPF 475 forwards the filtered values on path 476 to adder 155B of CKT-3. The BW (BW3) of LPF 475 is designed to be equal to that of loop-3 (which in turn is substantially determined by the bandwidth of LPF 150B). The use of LPF 475 is optional. Thus, in another embodiment, LPF 475 is not implemented and the output of scaling block 470 is directly provided to adder 155B. Bypass path BP-2 operates in a manner similar to bypass path BP-1, except that BP-2 is used to bypass loop-3 in case of failure of loop-3, and the description is not provided here in the interest of conciseness.

MLFT 400 conforms to the requirements of the ITU-T standard G.8273.2. Thus, MLFT 400 is capable of tracking multiple grades of clocks with different levels of priority/transfer function., namely four grades of clocks XO, OCXO, SYNCE, GPS/1pps/PTP in order of increasing frequency precision and frequency stability. Further, it may be verified based on the description provided thus far, that MLFT 400 supports the following requirement of the standard noted above:
1) If all the clocks are available, then output clock 181 tracks GPS/ 1pps/PTP clock/signal.
2) If GPS/1pps/PTP clock is lost, then output clock 181 tracks SYNCE clock.
3) If SYNCE clock is lost, then output clock 181 tracks OCXO clock.
4) If OCXO clock is lost, then output clock 181 tracks fref.
5) After a steady-state duration with all clocks available, if any clock is lost [except fref], then output clock 181 has minimal phase/frequency transient/hit.
6) The different input/output jitter-attenuator phase transfer function are met.

The description is continued with respect to a MLFT in yet another embodiment of the present disclosure.

### 6. Improving Hardware Implementation Efficiency

FIG. 5 is a block diagram of a MLFT in another embodiment of the present disclosure. MLFT 500 is shown there containing blocks CKT-1, CKT-2, CKT-3, CKT-4, LPF 175 and LPF 575. The blocks of MLFT 500 numbered the same as those in FIG. 4 are as described above, and their description is not repeated in the interest of conciseness. Only the differences of MLFT 500 from MLFT 400 are noted below.

Scaling block 570A replaces scaling block 170 of FIG. 4, and is connected differently in MLFT 500 as shown in FIG. 5. Scaling block 570A receives the value on path 156B, multiplies the value by a scaling factor (noted below), and forwards the product to adder 160B on path 576A. LPF 175 directly receives the value on path 156B.

Scaling block 570B replaces scaling block 470 of FIG. 4, and is connected differently in MLFT 500 as shown in FIG. 5. Scaling block 570B receives the value on path 156C, multiplies the value by a scaling factor (noted below), and forwards the product to adder 160C on path 576B. LPF 575 directly receives the value on path 156C.

It may be observed that the only difference in MLFT 500 when compared with MLFT 400 of FIG. 4 is in the two bypass paths, which now respectively contain only LPF 175 and LPF 575, with the scaling block of a bypass path now being contained in the ‘direct correction’ path from a lower loop to the immediate higher loop. In an embodiment, scaling block 570A multiplies the value on path 156B by a factor DIV2/DIV1, and scaling block 570B multiplies the value on path 156C by a factor DIV3/DIV1.

The correction value (F) on path 156A in terms of ppm with respect to DIV1 is (F/DIV1*1000000). Since the scaling in LPF 175 is 1, the correction value H (in terms of ppm) at 156B will be (H/DIV1*1000000). The correction value (G) on path 576A in terms of ppm with respect to DIV2 is (G/DIV2*1000000) and this must be equal to the correction value of H (in terms of ppm). Therefore, the required scaling factor (to scale H to G) in scaling block 570A is (DIV2/DIV1). Using a similar analysis, the scaling factor of scaling block 570B is DIV3/DIV1.

One advantage of the implementation of FIG. 5 over that of FIG. 4 is that the hardware implementation in FIG. 5 is more efficient in that it requires fewer interconnection paths and corresponding hardware blocks/resources in some of the paths. Specifically, at least for the source clock frequencies noted above, and for fout 181 of 96 MHz or greater, the divisors needed in dividers 165A, 165B and 165C are progressively larger. Therefore, in the implementation of FIG. 4, the correction values (plus fixed divisor) applied to the dividers also need to be larger, therefore requiring more number of bits to represent the values and the paths on which they are provided.

As an example, the value on path 162C in FIG. 4 may be of the order of 500 (represented with an integer portion and a fractional portion). However, due to implementation of scaling block in the ‘direct correction’ path (here scaling block 570B, as an example) in FIG. 5, the value on path 156C can be smaller by a factor (DIV3/DIV1) with respect to the value on the path 576B, which can be a large number. Hence, in the example, each of paths 156C, 151C, 146C, LPF 150C and PFD 145C can be implemented to process/handle values with smaller bit-widths (as compared to these paths and blocks in FIG. 4 Figure). Only, paths 576B, 162C, scaling block 570B and adder 160C will need to handle correspondingly larger bit-widths. Similar hardware-savings is also achieved in CKT-3 due to implementation of scaling block 570A in the ‘direct correction’ path from node 156B to 162B.

Several benefits of an MLFT implemented as described herein are now briefly noted. The implementation of CKT-1 as a fractional frequency divider rather than as an analog phase locked loop (APLL) results in several benefits. For example, a fractional frequency divider needs smaller implementation area and consumes less power when compared to an APLL. Further, since inductors are not required to implement a fractional frequency divider (unlike an APLL) and due to the smaller implementation area, undesired spurs in the spectrum of clock fout 181 are smaller and fewer and/or can be managed more easily.

A MLFT implemented as described above can be incorporated in a larger device or system as described briefly next.

### 7. System

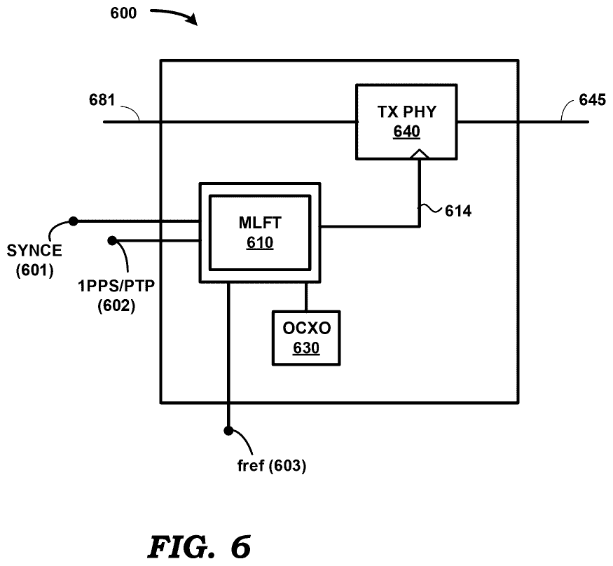

FIG. 6 is a block diagram of an example system containing a MLFT implemented according to various aspects of the present disclosure, as described in detail above. System 600 is a line card, shown containing MLFT 610, OCXO 630 and PHY Transmitter 640. MLFT 610 may be implemented as any of the MLFTs described in detail above. Line card 600 may operate consistent with corresponding standards (e.g., International Telecommunications Union (ITU) standards G.8262.1 and G.8273.2, and IEEE 1588) in packet networks. Line card 600 is used for re-timing data packets received over a network with respect to an available clock, and then transmitted in the physical layer. Line card 600 may be contained in a node (e.g., router) of a packet network.

Line card 600 receives a data packet on path 681, and forwards the packet on output path 645 after the packet has been re-timed (synchronized) with clock 614. The data packets may be generated by corresponding applications such as IPTV (Internet Protocol Television), VoIP (Voice over Internet Protocol), etc.

Clock 614 is generated by MLFT 610 based on clock fref 603, clock generated by OCXO 630 (oven-controlled crystal oscillator), SYNCE clock (601) and 1-PPS/PTP clock (602). Clock 614 corresponds to output clock fout 181 (or alternatively clock f-frac) of any of the MLFTs described above. MLFT 610 is designed to operate consistent with the ITU-T standard G.8273.2, and supports the above-noted requirements (numbered 1 through 6 above) of the standard.

### 8. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 6, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A multi-loop frequency translator (MLFT) to generate an output clock based on one or more clock sources, said MLFT comprising:
a plurality of loops containing a primary loop and a plurality of secondary loops according to a hierarchy,
wherein each loop of said plurality of loops is characterized by a corresponding specification frequency at which the loop is to ideally operate at,
wherein said primary loop is highest in said hierarchy and each of the secondary loops is completed by components of loops higher in said hierarchy,
wherein each loop at a lower level provides a corresponding correction signal to correct any drift from the specification frequency of a respective loop at one or more of the loops at higher levels,
wherein said primary loop is an open-loop circuit.

2. The MLFT of claim 1, wherein said open loop circuit is a fractional frequency divider (FFD).

3. The MLFT of claim 1, wherein each of said plurality of secondary loops comprises a corresponding phase locked loop (PLL),
wherein said one or more of the loops at higher levels is a loop at an immediately higher level.

4. The MLFT of claim 3, further comprising a set of bypass circuits,
wherein each bypass circuit is coupled between a first loop and a second loop located at least one skip-level higher in said hierarchy, and propagates a substitute signal as the corresponding correction signal from said first loop to said second loop when a loop at said skip-level is inoperative.

5. The MLFT of claim 4, wherein said fractional frequency divider (FFD) comprises:
a delta-sigma modulator (DSM) to generate a first repeating sequence of codes and a corresponding second repeating sequence of codes, wherein each code of said first repeating sequence of codes comprises an integer divisor, wherein each code of said second repeating sequence of codes comprises a delay value, wherein values of codes in each of said first repeating sequence and said second repeating sequence correspond to a desired fraction to be used by said fractional frequency divider;
a first frequency divider coupled to receive a reference clock and each code of said first repeating sequence of codes, and to divide a frequency of said reference clock by a value of each code in a corresponding time interval to generate a first divided clock; and
a digital-to-time converter (DTC) coupled to receive said first divided clock and said second repeating sequence of code, said DTC to generate a fractional clock from said first divided clock by delaying edges of interest of said first divided clock based on corresponding durations specified by corresponding codes in said second repeating sequence of codes,
wherein a frequency of said fractional clock equals a frequency of said reference clock divided by said desired fraction.

6. The MLFT of claim 5, wherein said FFD further comprises a calibration block to receive said second repeating sequence of codes and said fractional clock, said calibration clock to modify a value of each code in said second repeating sequence of codes to generate a corrected sequence of codes,
wherein said DTC delays said edges of interest of said first divided clock based on corresponding durations specified by corresponding codes of said corrected sequence of codes.
wherein modification of said value of each code in said second repeating sequence of codes corrects for a gain-error of said DTC,
wherein operation of said calibration block and said modification leave the frequency and phase of said first divided clock unaltered.

7. The MLFT of claim 5, wherein said FFD further comprises a second frequency divider to divide a frequency of said fractional clock by a factor of two to generate said output clock,
wherein a secondary loop immediately below said FFD in said hierarchy comprises:
said DSM and said first frequency divider;
a first phase-frequency detector (PFD) to receive a first clock and a first feedback clock, said PFD to generate a first error signal representing a phase difference between said first clock and said first feedback clock;
a first low-pass filter (LPF) to filter said first error signal to generate a first filtered error signal;
a first adder to generate a sum of said first filtered error signal and a first fixed divisor, wherein said first fixed divisor is said desired fraction, wherein said sum represents a first correction signal; and
a third frequency divider to receive a second correction signal from a secondary loop immediately lower in said hierarchy and to divide a frequency of said first divided clock by said second correction signal to generate said first feedback clock.

8. The MLFT of claim 7, wherein each of the rest of the plurality of secondary loops comprises:
the secondary loop immediately higher in said hierarchy;
a respective (PFD) to receive a respective clock and a respective feedback clock, said respective PFD to generate a respective error signal representing a phase difference between said respective clock and said respective feedback clock;
a respective low-pass filter (LPF) to filter said respective error signal to generate a respective filtered error signal;
a respective adder to generate a sum of said respective filtered error signal and a respective fixed divisor; and
a respective frequency divider to receive a respective correction signal from a respective secondary loop immediately lower in said hierarchy and to divide a frequency of said first divided clock by said respective correction signal to generate said respective feedback clock.

9. The MLFT of claim 8, wherein a bypass circuit of said set comprises a scaling block to scale a correction value from said first loop, said scaling block to forward a scaled correction value as said substitute signal to said second loop,
wherein said loop at said skip-level further comprises another adder to add said scaled correction value to the output of the LPF of said loop at said skip-level.

10. The MLFT of claim 9, wherein a scaling factor applied by said scaling block to scale said correction value equals a ratio of the fixed divisor of said second loop to the fixed divisor of said loop at said skip-level.

11. The MLFT of claim 10, wherein said bypass circuit further comprises a low-pass filter (LPF) to filter said scaled correction signal and to forward a filtered scaled correction signal to said first loop,
wherein said LPF is designed to have a same bandwidth as a bandwidth of said loop at said skip-level.

12. The MLFT of claim 8, wherein said correction value from said first loop is said respective filtered error signal of a corresponding one of said rest of the plurality of secondary loops,
wherein a bypass circuit of said set comprises a low-pass filter (LPF) to filter said respective filtered error signal of said first loop to generate a final filtered error signal, and to forward said final filtered error signal to said second loop by adding said final filtered error signal to the filtered error signal of said loop at said skip-level,
wherein said LPF is designed to have a same bandwidth as a bandwidth of said loop at said skip-level.

13. The MLFT of claim 12, wherein said each of the rest of the plurality of secondary loops further comprises:
a scaling block to scale a correction value from said first loop, said scaling block to forward a scaled correction value to said loop at said skip-level, said scaled correction value being added to a corresponding fixed value for the divisor of said respective frequency divider of said skip-level,
wherein a scaling factor applied by said scaling block equals a ratio of the fixed divisor of said second loop to the fixed divisor of the primary loop.

14. A system comprising:
a transmitter coupled to receive a first data packet, said line card to re-time said first data packet with reference to a re-timing clock, and to transmit a first re-timed packet; and
a multi-loop frequency translator (MLFT) to generate an output clock based on one or more clock sources, said MLFT comprising:
a plurality of loops containing a primary loop and a plurality of secondary loops according to a hierarchy,
wherein each loop of said plurality of loops is characterized by a corresponding specification frequency at which the loop is to ideally operate at,
wherein said primary loop is highest in said hierarchy and each of the secondary loops is completed by components of loops higher in said hierarchy,
wherein each loop at a lower level provides a corresponding correction signal to correct any drift from the specification frequency of a respective loop at one or more of the loops at higher levels,
wherein said primary loop is an open-loop circuit.

15. The system of claim 14, wherein said open loop circuit is a fractional frequency divider (FFD).

16. The system of claim 15, wherein each of said plurality of secondary loops comprises a corresponding phase locked loop (PLL),
wherein said one or more of the loops at higher levels is a loop at an immediately higher level.

17. The system of claim 16, further comprising a set of bypass circuits,
wherein each bypass circuit is coupled between a first loop and a second loop located at least one skip-level higher in said hierarchy, and propagates a substitute signal as the corresponding correction signal from said first loop to said second loop when a loop at said skip-level is inoperative.

18. The system of claim 17, wherein said fractional frequency divider (FFD) comprises:
a delta-sigma modulator (DSM) to generate a first repeating sequence of codes and a corresponding second repeating sequence of codes, wherein each code of said first repeating sequence of codes comprises an integer divisor, wherein each code of said second repeating sequence of codes comprises a delay value, wherein values of codes in each of said first repeating sequence and said second repeating sequence correspond to a desired fraction to be used by said fractional frequency divider;
a first frequency divider coupled to receive a reference clock and each code of said first repeating sequence of codes, and to divide a frequency of said reference clock by a value of each code in a corresponding time interval to generate a first divided clock; and
a digital-to-time converter (DTC) coupled to receive said first divided clock and said second repeating sequence of code, said DTC to generate a fractional clock from said first divided clock by delaying edges of interest of said first divided clock based on corresponding durations specified by corresponding codes in said second repeating sequence of codes,
wherein a frequency of said fractional clock equals a frequency of said reference clock divided by said desired fraction.

19. The system of claim 18, wherein said FFD further comprises a calibration block to receive said second repeating sequence of codes and said fractional clock, said calibration clock to modify a value of each code in said second repeating sequence of codes to generate a corrected sequence of codes,
wherein said DTC delays said edges of interest of said first divided clock based on corresponding durations specified by corresponding codes of said corrected sequence of codes. wherein modification of said value of each code in said second repeating sequence of codes corrects for a gain-error of said DTC,
wherein operation of said calibration block and said modification leave the frequency and phase of said first divided clock unaltered.

20. The system of claim 19, wherein said FFD further comprises a second frequency divider to divide a frequency of said fractional clock by a factor of two to generate said output clock,
wherein a secondary loop immediately below said FFD in said hierarchy comprises:
said DSM and said first frequency divider;
a first phase-frequency detector (PFD) to receive a first clock and a first feedback clock, said PFD to generate a first error signal representing a phase difference between said first clock and said first feedback clock;
a first low-pass filter (LPF) to filter said first error signal to generate a first filtered error signal;
a first adder to generate a sum of said first filtered error signal and a first fixed divisor, wherein said first fixed divisor is said desired fraction, wherein said sum represents a first correction signal; and
a third frequency divider to receive a second correction signal from a secondary loop immediately lower in said hierarchy and to divide a frequency of said first divided clock by said second correction signal to generate said first feedback clock,
wherein each of the rest of the plurality of secondary loops comprises:
the secondary loop immediately higher in said hierarchy;
a respective (PFD) to receive a respective clock and a respective feedback clock, said respective PFD to generate a respective error signal representing a phase difference between said respective clock and said respective feedback clock;
a respective low-pass filter (LPF) to filter said respective error signal to generate a respective filtered error signal;
a respective adder to generate a sum of said respective filtered error signal and a respective fixed divisor; and
a respective frequency divider to receive a respective correction signal from a respective secondary loop immediately lower in said hierarchy and to divide a frequency of said first divided clock by said respective correction signal to generate said respective feedback clock,
wherein a bypass circuit of said set comprises a scaling block to scale a correction value from said first loop, said scaling block to forward a scaled correction value as said substitute signal to said second loop,
wherein said loop at said skip-level further comprises another adder to add said scaled correction value to the output of the LPF of said loop at said skip-level.
